(19) United States
(12) Patent Application Publication
(10) Pub. No.: US 2002/0117711 A1
(43) Pub. Date: Aug. 29, 2002

(54) Semiconductor device and method of manufacturing the same

(76) Inventor: Tatsuo Yoneda, Yokohama-shi (JP)

Correspondence Address: Oblon, Spivak, McClelland, Maier & Neustadt P.C., 1755 Jefferson Davis Highway, Fourth Floor, Arlington, VA, 22202, US

(21) Appl. No.: 09/498,364

(22) Filed: Feb. 4, 2000

(30) Foreign Application Priority Data
Feb. 5, 1999 (JP) 11-028473

(51) Int. Cl. H01L 31/119; H01L 31/113; H01L 31/062; H01L 29/94; H01L 29/76

(52) U.S. Cl. 257/330

(57) ABSTRACT

The present invention provides a trench gate MOS transistor capable of reducing the threshold voltage required for a low voltage drive and, at the same time, capable of preventing the withstand voltage V_{SUS} from being lowered. In the trench gate MOS transistor of the present invention, a thick trench side wall oxide film is formed after the trench etching step, followed by removing the trench side wall oxide film and subsequently forming a gate insulating film. In forming the trench side wall oxide film, the corner portions at the bottom and opening portion of the trench, which have a rectangular cross sectional shape, are rounded to improve the breakdown voltage of the gate insulating film. Also, the impurity doped in a surface portion close to the trench side wall of the P-type base region is out-diffused into the thick trench side wall oxide film to lower the impurity concentration in the surface portion of the P-type base layer close to the trench side wall, making it possible to lower the threshold voltage without decreasing the withstand voltage V_{SUS} of the semiconductor device. The trench gate structure of the present invention makes it possible to manufacture a trench gate MOS transistor of a low voltage drive with a high manufacturing yield without bringing about problems such as reduction in the withstand voltage V_{SUS} and increase in the IDSS leakage current.

### BACKGROUND OF THE INVENTION

The present invention relates to a semiconductor device and a method of manufacturing the same, particularly, to a MOS transistor used for power and having a trench gate structure and a method of manufacturing the same.

The conventional power MOS transistor such as a MOSFET, an IGBT (Insulated Gate Bipolar Transistor) is being changed from a planar structure to a trench gate structure in compliance with the request by the market for the reduction of ON voltage.

FIG. 1 is a cross sectional view showing a conventional trench gate MOS transistor. Reference numeral 1 in the drawing denotes an N⁺ silicon substrate having a high impurity concentration. Reference numeral 2 denotes an N⁻ epitaxial layer. Reference numeral 3 denotes a P-type base region formed by diffusion of a P-type impurity. Reference numeral 4 denotes a source region consisting of an N⁺ high impurity concentration region formed by ion implantation and diffusion of an N-type impurity. The mark N⁺ represents an N-type semiconductor having a high impurity concentration. Likewise, the mark N-represents an N-type semiconductor having a low impurity concentration.

A trench extending through the P-type base region 3 to reach the N⁻ epitaxial layer 2 is formed in a central portion of the N⁺ source region 4, and a gate oxide film 5 is formed along the wall defining the trench. Further, a gate electrode 6 consisting of polycrystalline silicon (polysilicon) is buried in the gate oxide film 5 defining the trench.

The N⁺ silicon substrate 1 and the N⁻ epitaxial layer 2 collectively form a drain region of the MOS transistor, and a drain electrode 7 and a drain terminal 9 are mounted to the N⁺ silicon substrate 1. The gate electrode 6 serves to control the channel formed in a side wall surface of the trench in the P-type base region 3 through the gate oxide film 5. A gate terminal 11 is mounted to the gate electrode 6.

Also, a source electrode 8 and a source terminal 10 are mounted to the N⁺ source region 4. As shown in FIG. 1, the source electrode 8 is formed to cover partly the P-type base region 3 as well as the N⁺ source region 4 so as to play the role of imparting a bias (i.e., a substrate bias in a MOS structure) substantially equal to the source voltage to the P-type base region 3.

The trench gate MOS transistor described above is constructed not to include a series resistance of channel. This makes it possible to realize an ON voltage lower than that of the planar structure. The trench gate MOS transistor shown in FIG. 1 is also advantageous in that, since the channel plane can be formed in a direction perpendicular to the upper surface of the silicon substrate 1, the channel width, i.e., length in a direction perpendicular to the drain current, can be drastically increased, compared with the planar structure, making it possible to lower the ON voltage.

On the other hand, with rapid progress in the market of portable electronic appliances that can be operated by a battery such as a notebook type personal computer, a portable telephone, and a VTR having a camera integrated therein, it is strongly demanded to develop particularly a power MOS of low R_{ON}, i.e., low ON resistance, and low voltage drive that can be directly driven by a battery voltage.

In order to obtain a trench gate MOS transistor of a low voltage drive, it was customary to decrease the impurity concentration of the P-type base region 3. This method certainly makes it possible to lower the threshold voltage Vₜₕ of the MOS transistor required for the low voltage drive. However, the particular method is defective in that, for example, the breakdown withstand voltage such as V_{SUS} is lowered.

The term “withstand voltage V_{SUS}” noted above represents the breakdown voltage of the power MOS transistor at the time when the excess voltage over the specification value generated by the electromotive force through a loaded inductance of a transformer etc., which is ON/OFF switched in high speed, is applied between the source and the drain with the gate left open. The conventional trench gate MOS transistor shown in FIG. 1 is also defective in that, since the impurity concentration is low in the P-type base region 3, a leakage current, i.e., an IDSS leakage, tends to generate between the source and drain regions, leading to an unstable manufacturing yield.

### BRIEF SUMMARY OF THE INVENTION

As described above, it was customary in the conventional trench gate MOS transistor to lower the impurity concentration in the P-type base region in order to obtain a low R_{ON} device of a low voltage drive, making it possible to lower the threshold voltage Vₜₕ. However, a problem such as reduction in the breakdown withstand voltage, e.g., a lowered V_{SUS}, remains unsolved.

An object of the present invention, which has been achieved in an attempt to overcome the above-noted defects inherent in the prior art, is to provide a trench gate MOS transistor of a low voltage drive capable of reducing the threshold voltage Vₜₕ required for the low voltage drive and, at the same time, capable of preventing the withstand voltage V_{SUS} from being lowered by the reduction in the threshold voltage Vₜₕ.

The present invention provides a semiconductor device, particularly a trench gate MOS transistor of a low voltage drive, and a manufacturing method thereof, characterized in that a thick trench side wall oxide film is formed on the side wall of the trench as a post treatment of the trench side wall after the trench etching step, followed by removing the trench side wall oxide film and subsequently forming a gate oxide film.

According to a first aspect of the present invention, there is provided a semiconductor device, comprising a low impurity concentration layer of a first conductivity type formed on an upper surface of a semiconductor substrate constituting a first high impurity concentration layer of the first conductivity type; a base region consisting of a low impurity concentration layer of a second conductivity type partially formed on the upper surface of the low impurity concentration layer; a source region consisting of a second high impurity concentration layer of the first conductivity type partially formed on the upper surface of the base region; a trench formed in a central portion of the source region in a manner to extend through the base region to reach the low impurity concentration region of the first conductivity type; a gate electrode buried inside the trench with a gate insulating film interposed between the gate electrode and the inner wall of the trench; and a gate electrode lead portion extending from the gate electrode to reach on the insulated surface of the low impurity concentration layer of the second conductivity type, characterized in that the impurity concentration in a region close to the trench side wall of the base region has an impurity concentration gradient in a direction perpendicular to the trench side wall surface such that the impurity concentration in a region close to the trench side wall of the base region is made lower than that in the inner portion of the base region.

Also, the semiconductor device of the present invention is characterized in that the base impurity concentration in a surface portion close to the trench side wall has an impurity concentration gradient in a direction perpendicular to the side wall surface of the trench such that the impurity concentration in a surface portion close to the trench side wall of the base region is made lower than that in the inner portion of the base region, and that the impurity concentration in that portion of the base region which is positioned outside the source region in a periphery of the trench opening portion and positioned at least below the source electrode has an impurity concentration distribution in a direction perpendicular to the upper surface of the base region, the impurity concentration distribution differing from the impurity concentration gradient.

According to a second aspect of the present invention, there is provided a method of manufacturing a semiconductor device, comprising the step of forming a drain layer by forming a low impurity concentration layer of a first conductivity type by epitaxial growth on a semiconductor substrate constituting a first high impurity concentration layer of the first conductivity type; the step of selectively forming a base layer of a second conductivity type on the upper surface of the drain layer; the step of forming a source region consisting of a second high impurity concentration layer of the first conductivity type by ion implantation and diffusion of an impurity of the first conductivity type into a source formation region in the upper surface of the base layer, the source region being formed shallower than the thickness of the base layer; the step of forming a trench in a central portion of the source region by anisotropic etching in a manner to extend through the base region to reach the low impurity concentration layer of the first conductivity type; and the step of forming a trench side wall oxide film in a manner to cover at least the inner side wall of the trench, the impurity doped in the base layer being out-diffused in the step of forming the trench side wall oxide film from the surface portion of the base layer close to the side wall of the trench into the trench side wall oxide film to permit the base impurity concentration to form an impurity concentration gradient in a direction perpendicular to the trench side wall such that the impurity concentration in the surface portion close to the trench side wall of the base region is made lower than that in the inner portion of the base region.

According to a third aspect of the present invention, there is provided a method of manufacturing a semiconductor device, comprising the step of forming a drain layer by forming a low impurity concentration layer of a first conductivity type by epitaxial growth on a semiconductor substrate constituting a first high impurity concentration layer of the first conductivity type; the step of selectively forming a base layer of a second conductivity type on the upper surface of the drain layer; the step of ion implanting and diffusing an impurity of a second conductivity type into an upper surface of the base layer that is to be covered together with a source formation region by a source electrode in a subsequent step so as to increase the impurity concentration in a surface region of the base layer in at least a portion positioned below the source electrode; the step of forming a source region consisting of a second high impurity concentration layer of the first conductivity type by ion implantation and diffusion of an impurity of the first conductivity type into the source formation region in the upper surface of the base layer, the source region being formed shallower than the thickness of the base layer; the step of forming a trench in a central portion of the source region by anisotropic etching in a manner to extend through the base region to reach the low impurity concentration layer of the first conductivity type; the step of forming a trench side wall oxide film in a manner to cover at least the inner side wall of the trench, the source region, and the upper surface of the base layer including the source formation region, which are covered with the source electrode, the impurity doped in the base layer being out-diffused in the step of forming the trench side wall oxide film from the surface portion close to the trench side wall of the base layer into the trench side wall oxide film to permit the base impurity concentration in the surface portion close to the trench side wall to form an impurity concentration gradient in a direction perpendicular to the trench side wall such that the impurity concentration in the surface portion close to the trench side wall of the base layer is made lower than that in the inner portion of the base layer and to permit the impurity concentration in that portion of the base layer which is positioned outside the source region in the periphery of the trench opening and positioned below at least the source electrode to have an impurity concentration distribution differing from the impurity concentration gradient in a direction perpendicular to the upper surface of the base region such that the impurity concentration in the surface portion of the base layer is made higher than that in the inner portion of the base layer.

In a preferred embodiment of the method of the present invention for manufacturing a semiconductor device, the trench side wall oxide film is formed by a hydrogen burning oxidation at an oxidizing temperature of 950° C. It is also preferred to remove the trench side wall oxide film, followed by forming a gate insulating film having a predetermined thickness in a manner to cover the surface portion of the base layer exposed to the inner side wall of the trench.

The trench side wall oxide film formed by oxidizing the side wall of the trench makes it possible to decrease the impurity concentration in only the surface portion close to the trench side wall of the P-type base region without decreasing the entire base impurity concentration. It follows that it is possible to lower the threshold voltage Vₜₕ to a value adapted for the operation under a low voltage without decreasing the breakdown withstand voltage V_{SUS} of the trench gate MOS transistor.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a cross sectional view showing a conventional trench gate MOS transistor;

FIG. 2 is a cross sectional view showing a trench gate MOS transistor according to one embodiment of the present invention;

FIG. 3 is a graph showing the impurity concentration distribution in the surface region on the side of the trench side wall of the P-type base region in the structure of the present invention and in the conventional structure;

FIGS. 4A to 4H are cross sectional views collectively showing the process of manufacturing a trench gate MOS transistor of the present invention; and

FIG. 5 is a graph showing the relationship between the thickness of the trench side wall oxide film and the base surface impurity concentration in the trench side wall.

### DETAILED DESCRIPTION OF THE INVENTION

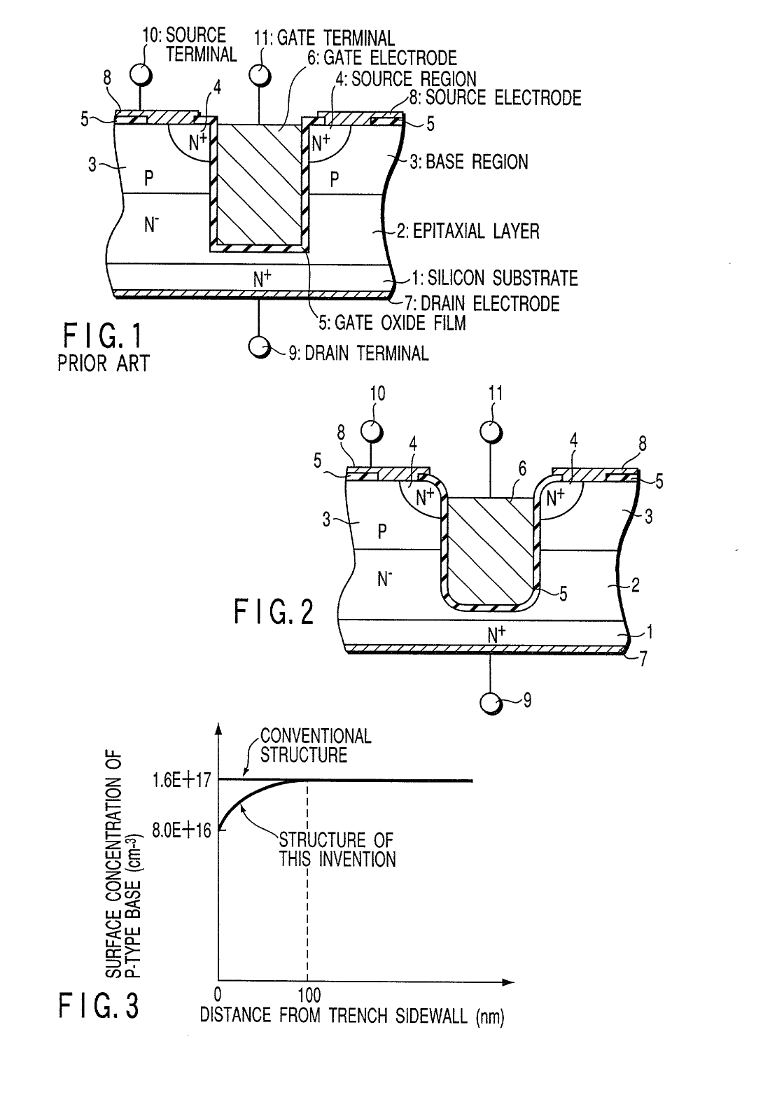

One embodiment of the present invention will now be described in detail with reference to the accompanying drawings. Specifically, FIG. 2 is a cross sectional view showing the construction of a trench gate MOS transistor according to a first embodiment of the present invention. The reference numerals common with FIGS. 1 and 2 denote the same members of the transistor and, thus, the explanation thereof are omitted in the following description for the sake of brevity.

The trench gate MOS transistor shown in FIG. 2 differs from the conventional MOS transistor shown in FIG. 1 in that the right angle edge portions in the periphery of the trench opening formed by a trench etching of silicon by, for example, RIE (Reactive Ion Etching) are rounded so as to increase the radius of curvature of each of the shoulder portion and the bottom corner portion of the trench.

As will be described herein later, a trench of a rectangular cross sectional shape is formed first by RIE, followed by introducing a trench side wall oxidation step so as to form a trench side wall oxide film on the inner surface of the trench. In the process of conversion of the silicon surface region into an oxide, the corner portion of the trench having a rectangular cross sectional shape is converted into a curved surface. As a result, a large radius of curvature is obtained in each of the shoulder portion and the bottom corner portion of the trench in the present invention.

The gate oxide film 5 shown in FIG. 2 is formed by removing the trench side wall oxide film so as to expose the silicon surface on the inner wall of the trench whose corner portions have been rounded, followed by applying the ordinary gate oxide film forming process.

The trench gate MOS transistor of the present invention is also featured in that the P-type impurity, e.g., boron, added from the surface portion of the P-type base region 3 is out-diffused in the step of oxidizing the trench side wall, with the result that the impurity concentration in the surface region of the trench side wall is lowered, as shown in FIG. 3. Specifically, FIG. 3 is a graph showing the relationship between the distance of the P-type base region 3 from the surface constituting a part of the trench side wall and the boron concentration in the P-type base region 3. As shown in the graph, the boron concentration in the inner region of the P-type base region is 1.6E+17 cm⁻³, which corresponds to 1.6×10¹⁷ cm⁻³. On the other hand, the boron concentration in the surface region is 8.0E+16 cm⁻³, which is about half the boron concentration in the inner region of the P-type base layer 3. In the trench side wall oxidation step, a hydrogen burning method was carried out at 950° C. Also, the trench side wall oxide film formed was found to have a thickness of 100 nm.

For comparison, FIG. 2 also shows that the boron concentration in the P-type base region was found to be uniform in the conventional trench gate MOS transistor shown in FIG. 1, in which the gate oxide film was formed directly on the inner wall of the trench formed by RIE and having a rectangular cross sectional shape. Where, for example, a thermal oxide film of silicon is used as the gate oxide film, the thickness of the gate oxide film was found to be only scores of nanometers, which is much smaller than the thickness of the trench side wall oxide film. As a result, the amount of out-diffusion of boron into the gate oxide film was small. As a result, the P-type base layer of the conventional structure including the surface region exhibits a uniform distribution of boron concentration.

It should be noted that the effect of decreasing the boron concentration in a surface region of the P-type base layer, which is produced by the introduction of the trench side wall oxidizing process, is rendered particularly prominent in the case where the thickness of the trench side wall oxide film is larger than the thickness of the gate oxide film.

As described previously, in order to obtain a trench gate MOS transistor of a low voltage drive, it is necessary to lower the threshold voltage required for the low voltage drive while maintaining the endurance to the excess voltage between the source and drain regions of the MOS transistor.

The threshold voltage was decreased in the past by lowering the boron concentration in the entire P-type base region 3. As a result, a serious problem was brought about that a local thermal run-away was caused by an excess voltage between the drain and source regions, leading to a marked reduction in the withstand voltage V_{SUS} of the device. Also, the IDSS leakage current was likely to be generated between the drain and source regions so as to lower the yield.

However, in the trench gate MOS transistor of the present invention in which the boron concentration is lowered in only the surface region of the P-type base region as shown in FIG. 3, the threshold voltage Vₜₕ can be lowered and, at the same time, the boron concentration is left unchanged in the inner region of the P-type base region. As a result, a prominent effect can be produced that the reduction in the withstand voltage V_{SUS} between the drain and source regions can be avoided and, at the same time, the IDSS leakage current between the drain and source regions does not take place.

It should also be noted that, in the conventional trench gate MOS transistor, the breakdown voltage between the gate and the source and between the gate and the drain was lowered because the gate oxide film is rendered thin by an anomalous growth in corner portions of the trench having a rectangular cross sectional shape. However, in the trench gate structure of the present invention in which each of the shoulder portion and the bottom corner portion of the trench has a large radius of curvature, the corner portions of the trench are covered with a gate oxide film having a uniform thickness. It follows that it is possible to prevent the reduction in the breakdown voltage between the gate and the source and between the gate and the drain so as to obtain a trench gate MOS transistor at a high manufacturing yield.

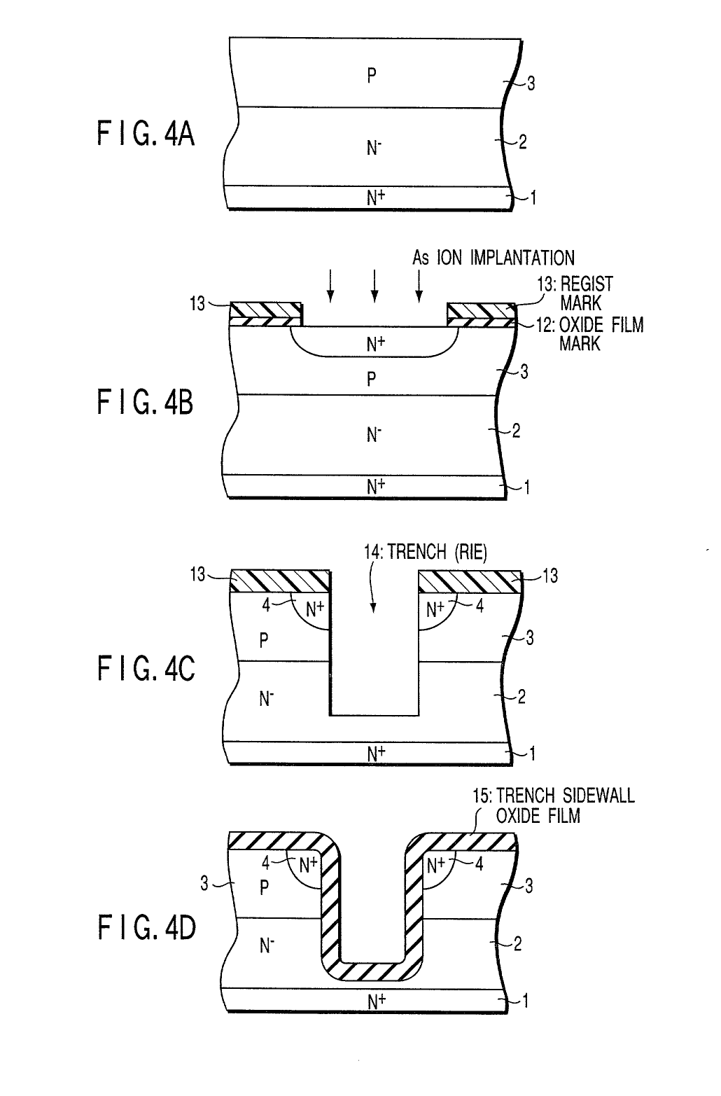

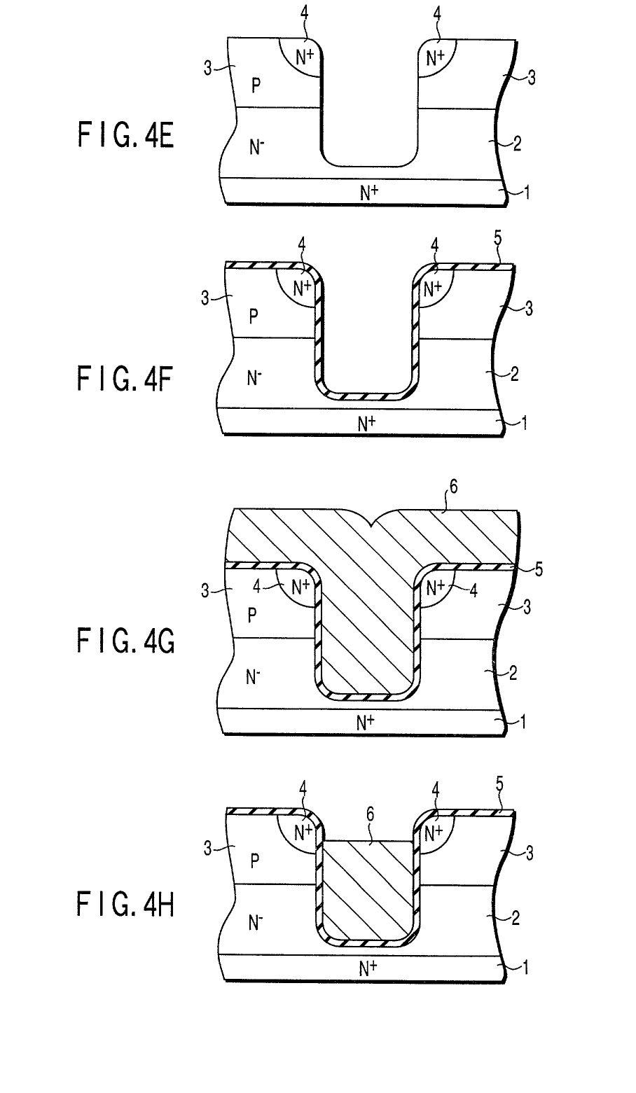

FIGS. 4A to 4H collectively show a method of manufacturing a trench gate MOS transistor according to a second embodiment of the present invention. As shown in FIG. 4A, an N⁻ epitaxial layer 2 is formed on a N⁺ silicon substrate 1, followed by forming a P-type base layer 3 by selectively diffusing boron into a P-type base forming region of the N⁻ epitaxial layer 2 by using a diffusion mask (not shown). Incidentally, FIG. 4A is a cross sectional view showing in a magnified fashion the trench-forming region. Therefore, the P/N⁻ junction in the peripheral portion of the P-type base region is not shown in the drawing.

In the next step, a laminate structure consisting of a SiO₂ film and a resist film is formed on the upper surface of the P-type base region 3, followed by patterning the laminate structure to form on the P-type base region 3 a laminate structure consisting of an oxide film mask 12 consisting of SiO₂ and a resist mask 13 formed on the oxide film mask 12, as shown in FIG. 4B. Then, a high concentration of, for example, arsenic (As) ions are implanted into a surface region of the P-type base region 3 by using the laminate structure of the oxide film mask 12 and the resist mask 13 as an ion implantation mask, followed by removing the resist mask 13 and subsequently applying a thermal diffusion treatment so as to form the N⁺ source region 4. After removal of the mask pattern, a resist mask 13 for dry etching such as RIE is formed in a central portion of the N⁺ source region 4 formed previously, followed by forming a trench 14 extending through the N⁺ source region 4 and the P-type base region 3 to reach an inner region of the N⁻ epitaxial layer 2, as shown in FIG. 4C. It should be noted that each of the corners in the bottom portion and the opening portion of the trench 14 formed by the dry etching such as RIE has a sharp right angle, as shown in FIG. 4C.

After formation of the trench 14, the inner surface of the trench 14 having a rectangular cross sectional shape and the upper surface of the silicon substrate are oxidized by a trench side wall oxidizing process using a hydrogen burning oxidizing method at 950° C. so as to form a trench side wall oxide film 15, as shown in FIG. 4D. In the case of employing a hydrogen burning oxidizing method, water vapor is generated within the reactor so as to carry out a wet oxidation to form a silicon oxide film having a thickness of about 100 nm under mild conditions that the inner surface of the trench 14 and the upper surface of the silicon substrate are heated for only about 10 minutes at a low temperature of 950° C. If a thick oxide film is formed by the heat treatment under a low temperature for a short time, the manufacturing process up to the trench formation is not adversely affected. Therefore, the thick film formation by a heat treatment under a low temperature for a short time is an important process condition.

As already described, the corner portions at the bottom and the opening portion of the trench are converted to form curved surfaces by the trench side wall oxidizing process. In addition, boron atoms are out-diffused from the inner surface within the trench of the P-type base region 3 into the trench side wall oxide film 15 so as to lower the boron concentration in the side wall of the P-type base region 3. Since boron exhibits a large diffusion coefficient within a silicon layer and a silicon oxide film, boron atoms are sufficiently out-diffused from the P-type base region 3 into the trench side wall oxide film 15 by the heat treatment under the low temperature for a short time given above.

In the next step, the trench side wall oxide film 15 is removed, as shown in FIG. 4E, followed by forming a gate oxide film 5, which is very thin compared with the trench side wall oxide film 15, by, for example, a thermal oxidation of silicon, as shown in FIG. 4F. In this step, the gate oxide film 5 can be formed in a uniform thickness over the entire inner surface of the trench 14 and the upper surface of the substrate, because the corners in the bottom portion and the opening portion of the trench 14 are moderately curved.

After formation of the gate oxide film 5, a conductive polysilicon is deposited on the entire surface including the inner region of the trench 14 by an ordinary method, followed by removing by using a dry etching such as RIE that portion of the conductive polysilicon 6 which is deposited on the substrate surface, as shown in FIG. 4G. As a result, a gate electrode 6 consisting of the conductive polysilicon is buried in the inner region of the trench 14, as shown in FIG. 4H. Further, a source electrode 7 and a drain electrode 8 are formed and connection terminals 9 to 11 are mounted as shown in FIG. 2 so as to finish manufacture of the trench gate MOS transistor of the present invention.

If the trench side wall oxide film 15 is formed in the trench side wall oxidizing step shown in FIG. 4D to cover not only the inner wall of the trench 14 but also the upper surfaces of the N⁺ source region 4 and the P-type base region 3 positioned outside the N⁺ source region 4, the reduction in the boron concentration in the surface region of the P-type base region 3, which was described previously with reference to FIG. 3, also takes place in the upper surface region of the P-type base region 3 positioned adjacent to the N⁺ source region 4.

The source electrode 8 is formed to cover the N⁺ source region 4 and to cover partly that portion of the P-type base region 3 which is positioned adjacent to the N⁺ source region 4 so as to apply a bias voltage substantially equal to the source voltage to the P-type base region 3. It should be noted in this connection that, if the boron concentration in the surface region of the P-type base region 3 is lowered in the trench side wall oxidizing step, a high resistance is provided between the upper surface of the P-type base region 3 and the source electrode, with the result that the P-type base region 3 tends to be put in a floating state.

In order to avoid the problem noted above, it is necessary to increase in advance the impurity concentration in the upper surface region of the P-type base region 3 by implanting and diffusing p-type impurity onto at least the upper surface of the P-type base region 3 forming a contact surface with the source electrode 8 so as to prevent the impurity concentration in the surface region of the P-type base region 3 from being excessively lowered in the trench side wall oxidizing process. Such being the situation, the impurity concentration of the P-type base region 3 in a region close to the trench side wall is required to have an impurity concentration gradient in a direction perpendicular to the trench side wall such that the impurity concentration is gradually increased from the surface region close to the trench side wall toward inner region. At the same time, the impurity concentration in that portion of the P-type base region 3 which is positioned outside the source region and at least the region below the source electrode 8 in the periphery of the trench opening portion is required to have an impurity concentration distribution in a direction perpendicular to the upper surface of the base region, said impurity concentration distribution differing from the impurity concentration gradient pointed out above.

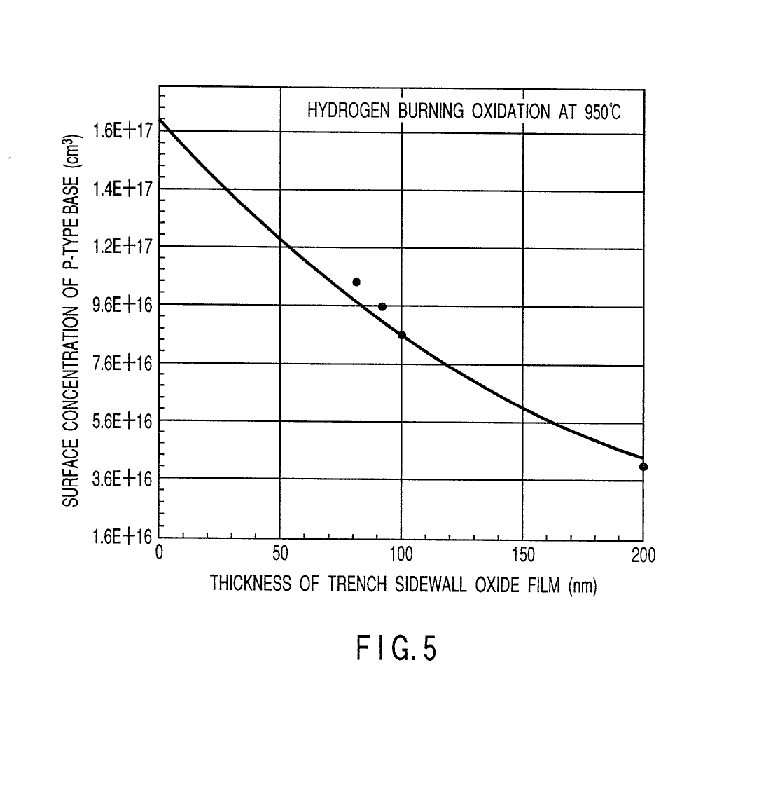

A third embodiment of the present invention will now be described with reference to a graph shown in FIG. 5. The third embodiment is based on an experiment conducted particularly in an attempt to look into the relationship between the out-diffusion amount of boron contained in the P-type base region 3 into the trench side wall oxide film 15 and the thickness of the trench side wall oxide film 15. In the graph of FIG. 5, the thickness (nm) of the trench side wall oxide film 14 is plotted on the abscissa, and the boron concentration per unit volume in that portion of the P-type base region 3 which is positioned close to the trench side wall is plotted on the ordinate. The trench side wall oxidizing process was carried out by a hydrogen burning oxidizing method at 950° C.

As shown in FIG. 5, the boron concentration in the surface region of the P-type base region 3 is rapidly decreased with increase in the thickness of the trench side wall oxide film 14 with a high reproducibility.

As described above, the boron concentration in a surface region close to the trench side wall of the P-type base region 3 can be decreased, with the boron concentration in the inner region of the P-type base region 3 left unchanged, by employing the trench side wall oxidizing process before formation of the gate insulating film. Since the boron concentration in the inner region of the P-type base region 3 is left unchanged, the withstand voltage V_{SUS} can be maintained and, at the same time, occurrence of the IDSS leakage can be avoided. In addition, since the boron concentration in the surface region of the P-type base region can be lowered, a trench gate MOS transistor having a low threshold voltage Vₜₕ required for the low voltage drive can be manufactured at a high manufacturing yield.

The present invention is not limited to the embodiments described above. In other words, the semiconductor device of the present invention can be modified in various fashions within the technical scope of the present invention.

As described above, the present invention provides a semiconductor device and a method of manufacturing the same. To be more specific, the present invention is directed to a trench gate MOS transistor for a power device, particularly, to a trench gate MOS transistor of a low voltage drive. In the present invention, a trench side wall oxidizing process is employed after the trench formation so as to permit boron atoms contained in a surface region close to the trench side wall of the P-type base region to be out-diffused into the trench side wall oxide film. As a result, the boron concentration in a surface region close to the trench side wall of the P-type base region can be selectively lowered so as to impart a low threshold voltage required for a low voltage drive of the MOS transistor.

What should also be noted is that, since the boron concentration in a surface region close to the trench side wall of the P-type base region can be selectively lowered while keeping the boron concentration in the inner region of the P-type base region unchanged, it is possible to prevent the withstand voltage V_{SUS} from being lowered and to prevent the IDSS leakage from being increased. In addition, the bias voltage applied to the P-type base region through the source electrode can be kept stable, making it possible manufacture a trench gate MOS transistor of a low voltage drive with a stable manufacturing yield.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device, comprising:
a low impurity concentration layer of a first conductivity type formed on an upper surface of a semiconductor substrate constituting a first high impurity concentration layer of the first conductivity type;
a base region consisting of a low impurity concentration layer of a second conductivity type partially formed on the upper surface of said low impurity concentration layer;
a source region consisting of a second high impurity concentration layer of the first conductivity type partially formed on the upper surface of said base region;
a trench formed in a central portion of said source region in a manner to extend through the base region to reach the low impurity concentration region of the first conductivity type;
a gate electrode buried inside said trench with a gate insulating film interposed between said gate electrode and the inner wall of the trench; and
a gate electrode lead portion extending from the gate electrode to reach on the insulated surface of the low impurity concentration layer of the second conductivity type,
characterized in that the impurity concentration in a region close to the trench side wall of said base region has an impurity concentration gradient in a direction perpendicular to the trench side wall surface such that the impurity concentration in a region close to the trench side wall of said base region is made lower than that in the inner portion of the base region.

2. A semiconductor device, comprising:
a low impurity concentration layer of a first conductivity type formed on an upper surface of a semiconductor substrate constituting a first high impurity concentration layer of the first conductivity type;
a base region consisting of a low impurity concentration layer of a second conductivity type partially formed on the upper surface of said low impurity concentration layer;
a source region consisting of a second high impurity concentration layer of the first conductivity type partially formed on the upper surface of said base region;
a trench formed in a central portion of said source region in a manner to extend through the base region to reach the low impurity concentration region of the first conductivity type;
a gate electrode buried inside said trench with a gate insulating film interposed between said gate electrode and the inner wall of the trench; and
a gate electrode lead portion extending from the gate electrode to reach on the insulated surface of the low impurity concentration layer of the second conductivity type,
characterized in that the base impurity concentration in a surface portion close to the trench side wall has an impurity concentration gradient in a direction perpendicular to the side wall surface of the trench such that the impurity concentration in a surface portion close to the trench side wall of the base region is made lower than that in the inner portion of the base region, and that the impurity concentration in that portion of the base region which is positioned outside the source region in a periphery of the trench opening portion and positioned at least below the source electrode has an impurity concentration distribution in a direction perpendicular to the upper surface of the base region, said impurity concentration distribution differing from said impurity concentration gradient.

3. A method of manufacturing a semiconductor device, comprising:
the step of forming a drain layer by forming a low impurity concentration layer of a first conductivity type by epitaxial growth on a semiconductor substrate constituting a first high impurity concentration layer of the first conductivity type;
the step of selectively forming a base layer of a second conductivity type on the upper surface of said drain layer;
the step of forming a source region consisting of a second high impurity concentration layer of the first conductivity type by ion implantation and diffusion of an impurity of the first conductivity type into a source formation region in the upper surface of the base layer, said source region being formed shallower than the thickness of the base layer;
the step of forming a trench in a central portion of the source region by anisotropic etching in a manner to extend through the base region to reach the low impurity concentration layer of the first conductivity type; and
the step of forming a trench side wall oxide film in a manner to cover at least the inner side wall of the trench, the impurity doped in the base layer being out-diffused in the step of forming the trench side wall oxide film from the surface portion of the base layer close to the side wall of the trench into the trench side wall oxide film to permit the base impurity concentration to form an impurity concentration gradient in a direction perpendicular to the trench side wall such that the impurity concentration in the surface portion close to the trench side wall of the base region is made lower than that in the inner portion of the base region.

4. The method of manufacturing a semiconductor device according to claim 3, wherein said trench side wall oxide film is formed by a hydrogen burning oxidation method performed at 950° C.

5. The method of manufacturing a semiconductor device according to claim 3, further comprising the step of removing said trench side wall oxide film, followed by forming a gate insulating film in a predetermined thickness in a manner to cover at least the surface portion of the base layer exposed to the inner side wall surface of said trench.

6. A method of manufacturing a semiconductor device, comprising:
the step of forming a drain layer by forming a low impurity concentration layer of a first conductivity type by epitaxial growth on a semiconductor substrate constituting a first high impurity concentration layer of the first conductivity type;
the step of selectively forming a base layer of a second conductivity type on the upper surface of said drain layer;
the step of ion implanting and diffusing an impurity of a second conductivity type into an upper surface of said base layer that is to be covered together with a source formation region by a source electrode in a subsequent step so as to increase the impurity concentration in a surface region of the base layer in at least a portion positioned below said source electrode;
the step of forming a source region consisting of a second high impurity concentration layer of the first conductivity type by ion implantation and diffusion of an impurity of the first conductivity type into the source formation region in the upper surface of the base layer, said source region being formed shallower than the thickness of the base layer;
the step of forming a trench in a central portion of the source region by anisotropic etching in a manner to extend through the base region to reach the low impurity concentration layer of the first conductivity type;
the step of forming a trench side wall oxide film in a manner to cover at least the inner side wall of the trench, said source region, and the upper surface of the base layer including the source formation region, which are covered with the source electrode, the impurity doped in the base layer being out-diffused in the step of forming the trench side wall oxide film from the surface portion close to the trench side wall of the base layer into the trench side wall oxide film to permit the base impurity concentration in the surface portion close to the trench side wall to form an impurity concentration gradient in a direction perpendicular to the trench side wall such that the impurity concentration in the surface portion close to the trench side wall of the base layer is made lower than that in the inner portion of the base layer and to permit the impurity concentration in that portion of the base layer which is positioned outside the source region in the periphery of the trench opening and positioned below at least the source electrode to have an impurity concentration distribution differing from said impurity concentration gradient in a direction perpendicular to the upper surface of the base region such that the impurity concentration in the surface portion of the base layer is made higher than that in the inner portion of the base layer.

7. The method of manufacturing a semiconductor device according to claim 6, wherein said trench side wall oxide film is formed by a hydrogen burning oxidation at an oxidizing temperature of 950° C.

8. The method of manufacturing a semiconductor device according to claim 6, further comprising the step of removing the trench side wall oxide film, followed by forming a gate insulating film having a predetermined thickness in a manner to cover the surface portion of the base layer exposed to the inner side wall of the trench.
